(19) United States
(12) Patent Application Publication
(10) Pub. No.: US 2025/0022909 A1
(43) Pub. Date: Jan. 16, 2025

(54) SEMICONDUCTOR DEVICES INCORPORATING QUANTUM DOTS

(71) Applicant: Saphlux, Inc., Branford, CT (US)

(72) Inventors: Jie Song, Branford, CT (US); Chen Chen, Branford, CT (US)

(73) Assignee: Saphlux, Inc., Branford, CT (US)

(21) Appl. No.: 18/352,923

(22) Filed: Jul. 14, 2023

(51) Int. Cl. H01L 27/15

(52) U.S. Cl. CPC H01L 27/156

(57) ABSTRACT

In accordance with one or more aspects of the present disclosure, an apparatus including micro-LEDs is provided. The apparatus may include a first nanoporous structure fabricated on a first light-emitting device and a second nanoporous structure fabricated on a second light-emitting device. A first plurality quantum dots are placed in the first nanoporous structure for converting light emitted by the first light-emitting device into light of a first color. A second plurality quantum dots are placed in the second nanoporous structure for converting light emitted by the second light-emitting device into light a second color. The apparatus further includes a third light-emitting device that emits light of a third color. The apparatus further includes a conductive layer of a conductive material. The conductive layer contacts the top surfaces of the first light-emitting device, the second surface of the second light-emitting device, and the third light-emitting device.

### TECHNICAL FIELD

The implementations of the disclosure relate generally to semiconductor devices and, more specifically, to semiconductor devices incorporating quantum dots (QDs) and methods of fabricating the same.

### BACKGROUND

Quantum dots (QDs) are semiconductor particles in nanoscale sizes. When a QD is illuminated by light, an electron in the QD may be excited to a state of higher energy. The QD may thus emit light of a certain wavelength. QDs of various shapes, sizes, compositions, etc. may emit light with various wavelengths. For example, a relatively larger QD may emit light with a relatively longer wavelength, while a relatively smaller QD may emit light with a relatively shorter wavelength.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with one or more aspects of the present disclosure, an apparatus is provided. The apparatus includes: a first nanoporous structure fabricated on a first surface of a first light-emitting device, wherein a first plurality quantum dots are placed in the first nanoporous structure for converting light emitted by the first light-emitting device into light of a first color; a second nanoporous structure fabricated on a second surface of a second light-emitting device, wherein a second plurality quantum dots are placed in the second nanoporous structure for converting light emitted by the second light-emitting device into light a second color; a third light-emitting device that emits light of a third color, and a conductive layer including a conductive material, wherein at least a portion of the conductive layer is fabricated in a first trench between the first light-emitting device and the second light-emitting device, and wherein the conductive layer contacts the first surface of the first light-emitting device, the second surface of the second light-emitting device, and a third surface of the third light-emitting device.

In some embodiments, a first lateral dimension of the first light-emitting device is greater than a second lateral dimension of the first nanoporous structure.

In some embodiments, the apparatus further includes a substrate including complementary metal-oxide-semiconductor (CMOS) circuitry. The apparatus further includes a dielectric layer, wherein at least a first portion of the dielectric layer is positioned between the substrate and the conductive layer.

In some embodiments, the apparatus further includes a distributed Bragg reflector (DBR) on the first nanoporous structure and the second nanoporous structure.

In some embodiments, the apparatus further includes a plurality of micro-lenses fabricated on the DBR.

In some embodiments, the conductive material includes a metallic material.

In some embodiments, the apparatus further includes a third nanoporous structure on the third light-emitting device, wherein no quantum dots are placed in the third nanoporous structure.

In some embodiments, at least a portion of the conductive layer is fabricated in a second trench between the second light-emitting device and the third light-emitting device.

In some embodiments, each of the first light-emitting device, the second light-emitting device, and the third light-emitting device is a micro light-emitting device.

In some embodiments, the first surface of the first light-emitting device is a top surface of an n-GaN layer of the first light-emitting device.

In some embodiments, the apparatus further includes insulating materials disposed on the conductive layer and in a plurality of trenches between the first nanoporous structure, the second nanoporous structure, and a third nanoporous structure. The third nanoporous structure is formed on the third light-emitting device.

According to one or more aspects of the present disclosure, methods for fabricating the apparatus are provided. The methods include: fabricating a plurality of micro semiconductor devices, wherein a first micro semiconductor device of the micro semiconductor devices includes a first nanoporous structure fabricated on a first top surface of a first light-emitting device, wherein a second micro semiconductor device of the micro semiconductor devices includes a second nanoporous structure fabricated on a second top surface of a second light-emitting device, and wherein a third micro semiconductor device of the micro semiconductor devices includes a third nanoporous structure fabricated on a third top surface of a third light-emitting device; and fabricating a conductive layer including a conductive material, wherein the conductive layer contacts the first top surface of the first light-emitting device, the second top surface of the second light-emitting device, and the third top surface of the third light-emitting device, and wherein at least one portion of the conductive layer is fabricated in a trench between the first light-emitting device and the second light-emitting device.

In some embodiments, the methods further include placing a first plurality of quantum dots in the first nanoporous structure for converting light produced by the first light-emitting device into light of a first color; and placing a second plurality of quantum dots in the second nanoporous structure for light produced by the second light-emitting device into light of a second color.

In some embodiments, the methods further include fabricating a protection layer on the first nanoporous structure and the second nanoporous structure.

In some embodiments, the methods further include: disposing a color filter on one or more of the micro semiconductor devices; and disposing a plurality of micro-lenses on the color filter.

In some embodiments, fabricating the plurality of micro semiconductor devices includes: forming a light-emitting structure and a semiconductor layer on a substrate; forming a plurality of nanoporous structures in the semiconductor layer, and fabricating a plurality of light-emitting devices in the light-emitting structure.

In some embodiments, fabricating the light-emitting structure and the semiconductor layer on the substrate includes attaching a semiconductor device to the substrate; and selectively removing one or more portions of the semiconductor device to expose a surface of the semiconductor layer.

In some embodiments, forming the plurality of nanoporous structures in the semiconductor layer includes: forming a porous semiconductor layer by etching the semiconductor layer; and processing the porous semiconductor layer into the plurality of nanoporous structures by etching the porous semiconductor layer.

In some embodiments, fabricating the conductive layer includes: depositing a metallic material on a first portion of the first surface of the first light-emitting device that is not covered by the first nanoporous structure, a second portion of the second surface of the second light-emitting device that is not covered by the second nanoporous structure, and a third portion of the third surface of the third light-emitting device that is not covered by the third nanoporous structure.

In some embodiments, fabricating the conductive layer includes: forming a first plurality of dielectric layers covering the plurality of micro semiconductor devices; forming a second dielectric layer in the trenches; depositing a plurality of negative photoresists on the first plurality of dielectric layers; and depositing a conductive material on the negative photoresists and in the trenches.

In some embodiments, fabricating the conductive layer further includes removing the negative photoresists.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates a cross-sectional view of an example semiconductor device with embedded quantum dots in accordance with some embodiments of the present disclosure.

FIG. 2 is a diagram illustrating a cross-sectional view of an example semiconductor device including a light-emitting structure in accordance with some embodiments of the present disclosure.

FIGS. 3A, 3B, 3C, 3D, 3E, 3F, 3G, 3H, 3I, 3J, 3K, 3L, 3M, 3N, 3O, and 3P are diagrams illustrating cross-sectional views of structures related to a process for fabricating the semiconductor device of FIG. 1 in accordance with some embodiments of the present disclosure are illustrated.

FIG. 4 is a flow chart illustrating an example process for fabricating a semiconductor device with embedded quantum dots in accordance with some embodiments of the present disclosure.

FIGS. 5A, 5B, and 5C are flow charts illustrating example processes for fabricating micro semiconductor devices containing nanoporous structures in accordance with some embodiments of the present disclosure.

FIG. 6 is a flow chart of an example process for fabricating a conductive layer that provides electrical connections between light-emitting devices and one or more other devices in accordance with some embodiments of the present disclosure.

FIG. 7 depicts a schematic diagram illustrating an example pixel arrangement of an example display device in accordance with some embodiments of the present disclosure.

### DETAILED DESCRIPTION

Aspects of the disclosure provide for semiconductor devices incorporating light-emitting devices (LEDs) and quantum dots (QDs), and methods of fabricating the same. As an example, a semiconductor device in accordance with the present disclosure may include a plurality of light-emitting devices that can produce light that may be and/or include light-emitting diodes, laser diodes, and/or any other suitable devices capable of producing light. In some embodiments, each of the light-emitting devices may be and/or include a flip-chip light-emitting diode. The light-emitting devices may emit light of a certain color (e.g., blue light). Each of the light-emitting devices may be micro-LED with dimensions on the scale of micrometers. The light-emitting devices may be separated by a plurality of trenches.

The semiconductor device may further include a plurality of nanoporous structures corresponding to the light-emitting devices. A respective nanoporous structure may include one or more nanoporous materials comprising pores (e.g., voids) of nanoscale sizes (e.g., a size of the order of 1 nm to 1000 nm or larger) and may include quantum dots placed in the nanoporous materials for converting light produced by one or more of the light-emitting devices corresponding to the nanoporous structure. For example, a first nanoporous structure, a second nanoporous structure, and a third nanoporous structure may be fabricated on a first light-emitting device (e.g., a first micro-LED), a second light-emitting device (e.g., a second micro-LED), and a third-emitting device (e.g., a third micro-LED), respectively. The first nanoporous structure may include first quantum dots for converting light produced by the first light-emitting device into red light. The second nanoporous structure may include second quantum dots for converting light produced by the second light-emitting device into green light. The third nanoporous structure does not include quantum dots. The light produced by the third light-emitting device (e.g., blue light) may pass through the third nanoporous structure without being converted into light of different wavelengths and/or colors.

The semiconductor device may further include a conductive layer of one or more conductive materials (e.g., a layer of a metal such as titanium, gold, etc.). The light-emitting devices may be connected to one or more other components of the semiconductor device electrically via the conductive layer. In some embodiments, each of the nanoporous structures is formed on a first portion of a respective light-emitting device (e.g., the central portion of the respective light-emitting device). The conductive layer may contact a second portion of each of the light-emitting devices that is not covered by a nanoporous structure (e.g., a portion surrounding the central portion of each light-emitting device). One or more portions of the conductive layer may be fabricated in the trenches that separate the light-emitting devices. The contact between the conductive layer and the light-emitting devices may increase the current spreading, and may thus reduce the voltage of injection-driven power and improve the emission light power efficiency of the LEDs.

Examples of embodiments of the present disclosure will be described in more detail with reference to the accompanying drawings. It should be understood that the following embodiments are given by way of illustration only to provide a thorough understanding of the disclosure to those skilled in the art. Therefore, the present disclosure is not limited to the following embodiments and may be embodied in different ways. Further, it should be noted that the drawings are not to precise scale and some of the dimensions, such as width, length, thickness, and the like, can be exaggerated for clarity of description in the drawings. Like components are denoted by like reference numerals throughout the specification.

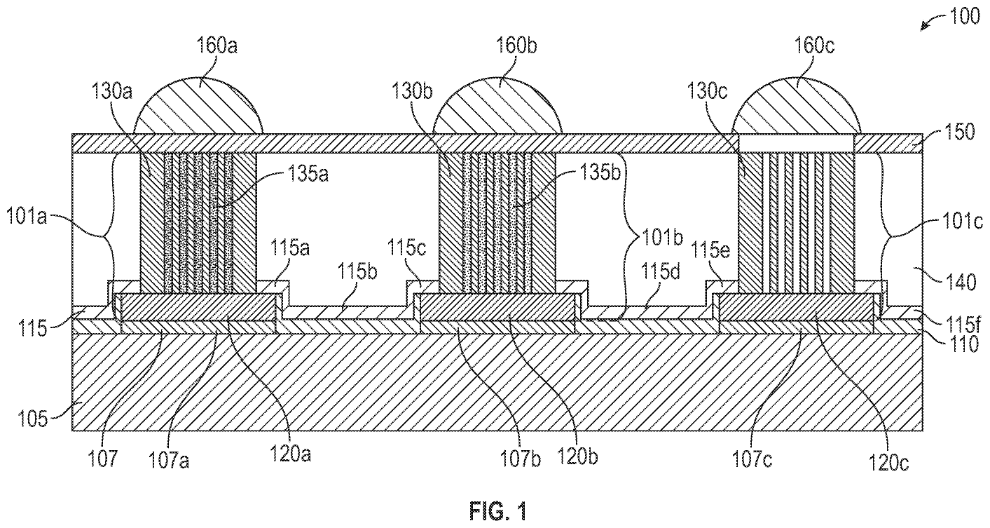

FIG. 1 illustrates a cross-sectional view of an example semiconductor device 100 in accordance with some embodiments of the present disclosure. Semiconductor device 100 may be part of a computing device (e.g., a watch, eyeglasses, contact lenses, a mobile phone, a head-mounted display, a tablet computing device, a laptop, a desktop computer, a television, an augmented reality (AR) device, a virtual reality (VR) device, etc.) and/or a display.

As shown, semiconductor device 100 may include light-emitting devices (LEDs) 120a, 120b, . . . , 120c fabricated on a substrate 105. Substrate 105 may include a silicon wafer in some embodiments. Substrate 105 may include any suitable component for enabling individual electronic control of the light-emitting devices and/or micro semiconductor devices to be fabricated on substrate 105. For example, substrate 105 may include one or more driver circuits (e.g., thin-film-transistor (TFT) driver circuits, CMOS driver circuits, etc.) that may control the brightness of each LEDs fabricated on substrate 105. As another example, substrate 105 may include complementary metal-oxide-semiconductor (CMOS) circuitry, such as one or more CMOS drivers, interconnects, etc.

Semiconductor device 100 may further include a plurality of light-emitting devices (a first LED 120a, a second LED 120b, a third LED 120c, etc.) formed on substrate 105. For example, LEDs 120a-c may be attached to substrate 105 via a bonding layer 107. The bonding layer may include any suitable material that may bond LEDs 120a-c to substrate 105, such as an Au—Sn alloy, indium, etc., which can establish a strong bonding strength and good ohmic contact for the p-GaN side on LEDs 120a-c. As shown in FIG. 1, first LED 120a, second LED 120b, and third LED 120c may be bonded to substrate 105 via segments 107a, 107b, and 107c of bonding layer 107, respectively.

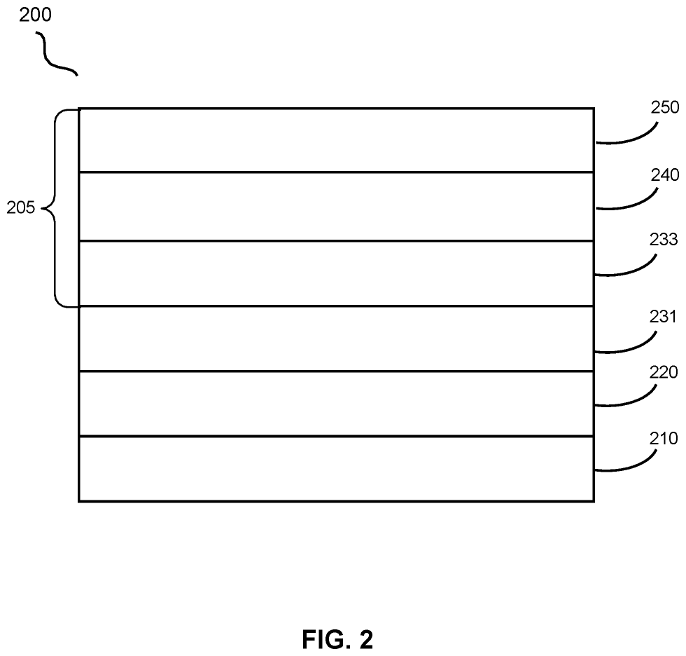

Each of LEDs 120a-c may be and/or include light-emitting diodes, laser diodes, and/or any other suitable devices capable of producing and/or emitting light. In some embodiments, LEDs 120a-c may emit blue light. Each LED 120a-c may include an n-GaN layer, a p-GaN layer, and an active layer between the n-GaN layer and the p-GaN layer. LEDs 120a-c may include any other suitable component for emitting light. In some embodiments, each of LEDs 120a-c may include a light-emitting structure 205 as described in connection with FIG. 2.

Each LED 120a-c may be a micro-LED in some embodiments. As referred to herein, a micro-LED may be an LED with dimensions on the scale of micrometers. In one implementation, a dimension (e.g., a lateral dimension) of a micro LED may be approximately 5-25 μm. In another implementation, a dimension (e.g., a lateral dimension) of the micro-LED may be greater than 25 μm or smaller than 5 μm. A pixel pitch between two neighboring LEDs 120a-c may be 20 μm, 25 μm, or of any other suitable value. In some embodiments, the pixel pitch may be equal to or greater than 20 μm. The pixel pitch may represent a distance between the light-emitting devices (e.g., a distance between a center of a first light-emitting device and a center of a second light-emitting device, a distance between a side of the first light-emitting device and a side of the second light-emitting device, etc.). While a certain number of LEDs are shown in FIG. 1, this is merely illustrative. Any suitable number of LEDs may be formed on substrate 105 as described herein to fabricate a display of a suitable size.

Semiconductor device 100 may further include nanoporous structures 130a, 130b, . . . , 130c formed on LEDs 120a, 120b, . . . , 120c. Each nanoporous structure 130a-130c may be and/or include nanoporous materials with nanopores having a nanoscale size (e.g., a size of the order of 1 nm to 1000 nm or larger). An LED and a nanoporous structure formed on the LED may also be referred to herein as a micro semiconductor device (e.g., micro semiconductor device 101a including LED 120a and nanoporous structure 130a, micro semiconductor device 101b including LED 120b and nanoporous structure 130b, micro semiconductor device 101c including LED 120c and nanoporous structure 130c, etc.). Nanoporous structures 130a-c may be separated by trenches coated with insulating materials 140. Insulating materials 140 may include any suitable material that may prevent and/or reduce optical crosstalk between neighboring nanoporous structures. In some embodiments, insulating materials 140 may include black material or combined black materials, such as black glue, epoxy, -dielectric sandwiched metal, etc. Each nanoporous structure 130a-c is aligned with and formed on a respective LED 120a-c. For example, a first nanoporous structure 130a, a second nanoporous structure 130b, and a third nanoporous structure 130c are formed on the top surface of a first LED 120a, the top surface of a second LED 120b, and the top surface of a third LED 120c, respectively. First nanoporous structure 130a, second nanoporous structure 130b, and third nanoporous structure 130c do not overlap with each other.

QDs may be placed in one or more nanoporous structures 130a-130c. The QDs may be and/or include semiconductor particles in nanoscale sizes (also referred to as “nanoparticles”). As an example, the nanoparticles may contain ZnS, ZnSe, CdSe, InP, CdS, PbS, InP, InAs, GaAs, GaP, etc. Each of the QDs may have a suitable core-shell structure that may include a core and/or one or more shells. The core and the shells may or may not include the same semiconductor material. As an example, one or more of the QDs may have a core comprising a suitable semiconductor material. As another example, one or more of the QDs may have a core comprising a first semiconductor material (e.g., CdS) and a shell comprising a second semiconductor material (e.g., ZnS). As a further example, one or more of the QDs may have a core (e.g., a CdSe core) and multiple shells (e.g., a first shell comprising ZnSe, a second shell comprising ZnS). Multiple QDs placed in the porous structure may or may not have the same core-shell structures.

When excited by electricity or light, a QD may emit light of a certain wavelength and/or a range of wavelengths (also referred to as the “emission wavelength” of the QD). More particularly, for example, the QD may absorb one or more photons with a wavelength shorter than the emission wavelength of the QD. Different QDs (e.g., QDs of various shapes, sizes, and/or materials) may emit light with various wavelengths. For example, a relatively larger QD may emit light with a relatively longer wavelength, while a relatively smaller QD may emit light with a relatively shorter wavelength.

First nanoporous structure 130a may be embedded with a first plurality of quantum dots 135a (also referred to as the “first QDs”) for converting light produced by first LED 120a into light of a first color (e.g., red light). Second nanoporous structure 130b may be embedded with a second plurality of quantum dots 135b (also referred to as the “second QDs”) for converting light produced by second LED 120b into light of a second color (e.g., green light). No second QDs are placed in first nanoporous structure 130a. Similarly, no first QDs are placed in second nanoporous structure 130b. In some embodiments, no quantum dots are placed in third nanoporous structure 130c.

As shown in FIG. 1, a lateral dimension of a given LED 120a-c is greater than a lateral dimension of a nanoporous structure 130a-c formed on the given LED. As such, at least a portion of the top surface of each LED 120a-c is not covered by a nanoporous structure 130a-c. For example, first nanoporous structure 130a may be formed on a central portion of the top surface of first LED 120a (also referred to as the “first top surface”). Second nanoporous structure 130b may be formed on a central portion of the top surface of second LED 120b (also referred to as the “second top surface”). Third nanoporous structure may be formed on a central portion of the top surface of third LED 120c (also referred to as the “third top surface”). One or portions of the first top surface, the second top surface, and the third top surface (e.g., a portion surrounding the central portion) are not covered by a nanoporous structure.

Semiconductor device 100 may further include a conductive layer 115 that may connect LEDs 120a-c to one or more other circuit elements (not shown) fabricated on substrate 105 electrically. Conductive layer 115 may contain any suitable conductive materials, such as one or more metallic materials. In some embodiments, conductive layer 115 may include a layer of titanium (Ti), gold (Au), and/or any other suitable metal. In some embodiments, conductive layer 115 directly contacts a semiconductor layer of the LEDs 120a-c that contain n-doped GaN. A voltage may be applied to LED 120a-c via conductive layer 115. In some embodiments, conductive layer 115 may connect an electrode (not shown in FIG. 1) and the n-GaN layer of a respective LED 120a-c. Conductive layer 115 may be fabricated on the portions of the top surfaces of LEDs 120a-c that are not covered by nanoporous structures 130a-c (e.g., the portions of the top surfaces surrounding the top portions of the top surfaces) and in the trenches that separate neighboring LEDs 120a-c. More particularly, as shown in FIG. 1, portions 115a, 115c, and 115e of conductive layer 115 may contact the top surface of first LED 120a (also referred to as the “first top surface”), the top surface of second LED 120b (also referred to as the “second top surface”), and a top surface of third LED 120c (also referred to as the “third top surface”), respectively. Conductive layer 115 may directly contact the portions of the first top surface, the second top surface, and the third top surface that are not covered by a nanoporous structure 130a-c. In some embodiments, semiconductor device 100 may further include a dielectric layer 110 fabricated in the trenches that separate LEDs 120a-c and on substrate 105. Dielectric layer 110 may include one or more layers of silicon oxide, silicon nitride, and/or any other suitable dielectric materials. Portions 115b, 115d, and 115f of conductive layer 115 may be fabricated on dielectric layer 110.

In some embodiments, semiconductor device 100 may further include a color filter 150, such as a DBR (distributed Bragg reflector), red glue and/or epoxy, green glue and/or epoxy, etc., fabricated on nanoporous structures 130a-c and insulating materials 140. Color filter 150 may include a distributed Bragg reflector (DBR) Color filter in some embodiments. Color filter 150 does not cover or contact third nanoporous structure 130c in some embodiments.

In some embodiments, semiconductor device 100 may further include micro-lenses 160a, 160b, . . . , 160c fabricated on color filter 150. Micro-lenses 160a, 160b, . . . , 160c may collimate the light beam produced by an LED and converge the light beam into a smaller emission angle.

FIG. 2 is a diagram illustrating a cross-sectional view of an example semiconductor device 200 in accordance with some embodiments of the present disclosure. Semiconductor device 200 may include a light-emitting structure 205 that may emit light.

As shown, semiconductor device 200 may include a growth template 210, a buffer layer 220, a first semiconductor layer 231 and a second semiconductor layer 233 containing a group III-V material doped with a first type of conductive impurity, an active layer 240, and a third semiconductor layer 250 containing the group III-V material doped with a second type of conductive impulsivity. In some embodiments, second semiconductor layer 233, active layer 240, and third semiconductor layer 250 may also be referred to as light-emitting structure 205.

Growth template 210 may include one or more epitaxial layers of the group III-V material (e.g., gallium nitride (GaN)) to be grown on the growth template 210 and/or a foreign substrate. The foreign substrate may contain any other suitable crystalline material that can be used to grow the group III-V material, such as sapphire, silicon carbide (SiC), silicon (Si), quartz, gallium arsenide (GaAs), aluminum nitride (AlN), etc.

Buffer layer 220 may include one or more epitaxial layers of the group III-V material (e.g., GaN) that are not doped with any particular conductive type of impurity.

First semiconductor layer 231 and second semiconductor layer 233 may include one or more epitaxial layers of group III-V materials and any other suitable semiconductor material (e.g., GaN) doped with the first type of conductive impurity. The first type of conductive impurity may be an n-type impurity in some embodiments. For example, each of first semiconductor layer 231 and second semiconductor layer 233 may include an n-GaN layer (e.g., a Si-doped GaN layer, a Ge-doped GaN layer, etc.). In some embodiments, first semiconductor layer 231 and second semiconductor layer 233 may be one epitaxial layer of n-GaN. In some embodiments, first semiconductor layer 231 and second semiconductor layer 233 may be multiple n-GaN layers and may or may not contain the same n-doped GaN.

Active layer 240 may include one or more layers of semiconductor materials and/or any other suitable material for emitting light. For example, active layer 240 may include an active layer comprising one or more quantum well structures for emitting light. Each of the quantum well structures may be and/or include a single quantum well structure (SQW) and/or a multi-quantum well (MQW) structure. Each of the quantum well structures may include one or more quantum well layers and barrier layers (not shown in FIG. 2). The quantum well layers and barrier layers may be alternately stacked on one another. The quantum well layers may include indium (e.g., indium gallium nitride). Each of the quantum well layers may be an undoped layer of indium gallium nitride (InGaN) that is not intentionally doped with impurities. Each of the barrier layers may be an undoped layer of the group III-V material that is not intentionally doped with impurities. A pair of a barrier layer (e.g., a GaN layer) and a quantum well layer (e.g., an InGaN layer) may be regarded as being a quantum well structure. Active layer 240 may contain any suitable number of quantum well structures. For example, the number of the quantum well structures (e.g., the number of pairs of InGaN and GaN layers) may be 3, 4, 5, etc.

Third semiconductor layer 250 may include one or more epitaxial layers of the group III-V material and/or any other suitable material. For example, third semiconductor layer 250 can include an epitaxial layer of the group III-V material doped with a second conductive type impurity that is different from the first conductive type impurity. For example, the second conductive type impurity may be a p-type impurity. In some embodiments, third semiconductor layer 250 may include a GaN layer doped with magnesium.

When energized, active layer 240 may produce and emit light. For example, when an electrical current passes through active layer 240, electrons from semiconductor layer 233 (e.g., an n-doped GaN layer) may combine in active layer 240 with holes from third semiconductor layer 250 (e.g., a p-doped GaN layer). The combination of the electrons and the holes may generate light. In some embodiments, active layer 240 may produce light of a certain color (e.g., light with a certain wavelength).

While certain layers of semiconductor materials are shown in FIG. 2, this is merely illustrative. For example, one or more intervening layers may or may not be formed between two semiconductor layers of FIG. 2 (e.g., between semiconductor layer 233 and active layer 240, between active layer 240 and third semiconductor layer 250, etc.). In one implementation, a surface of second semiconductor layer 233 may directly contact a surface of active layer 240. In another implementation, one or more intervening layers (not shown in FIG. 2) may be formed between second semiconductor layer 233 and active layer 240. One or more intervening layers (not shown in FIG. 2) may be formed between first semiconductor layer 231 and buffer layer 220.

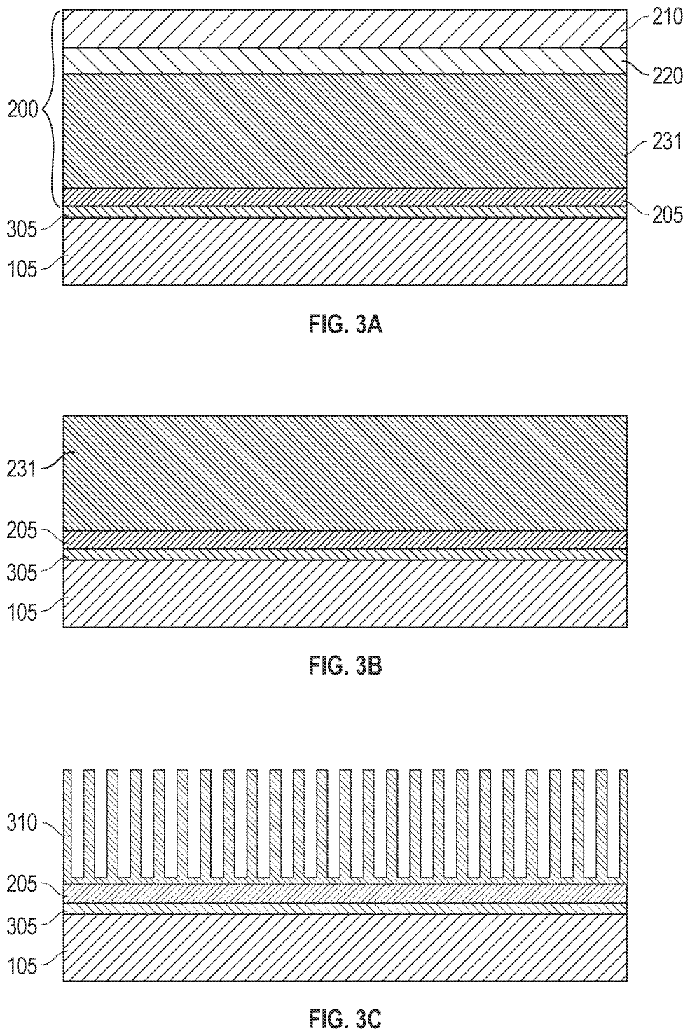

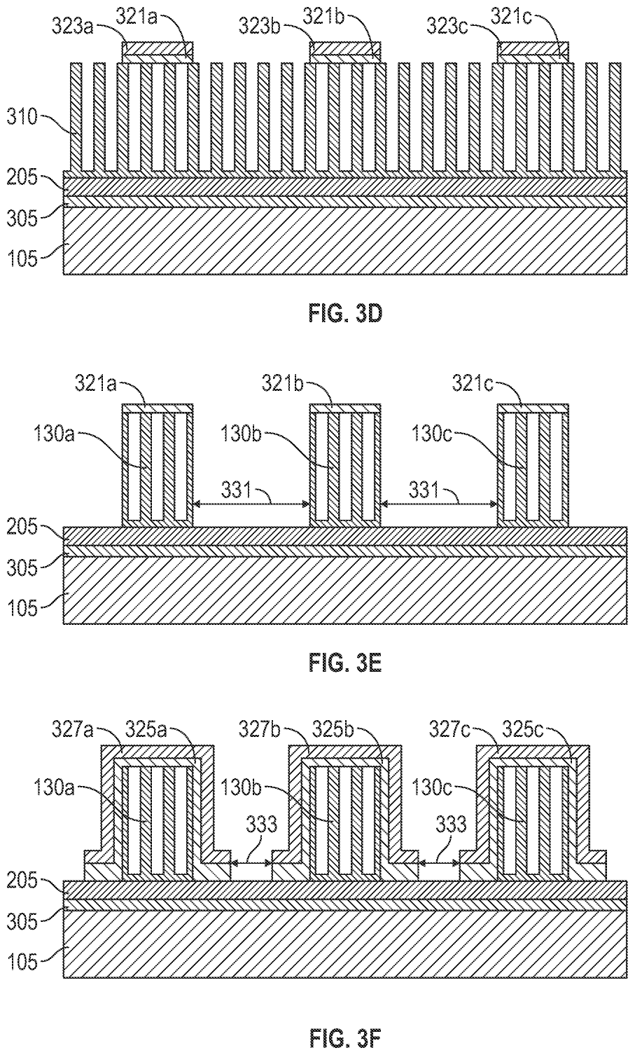

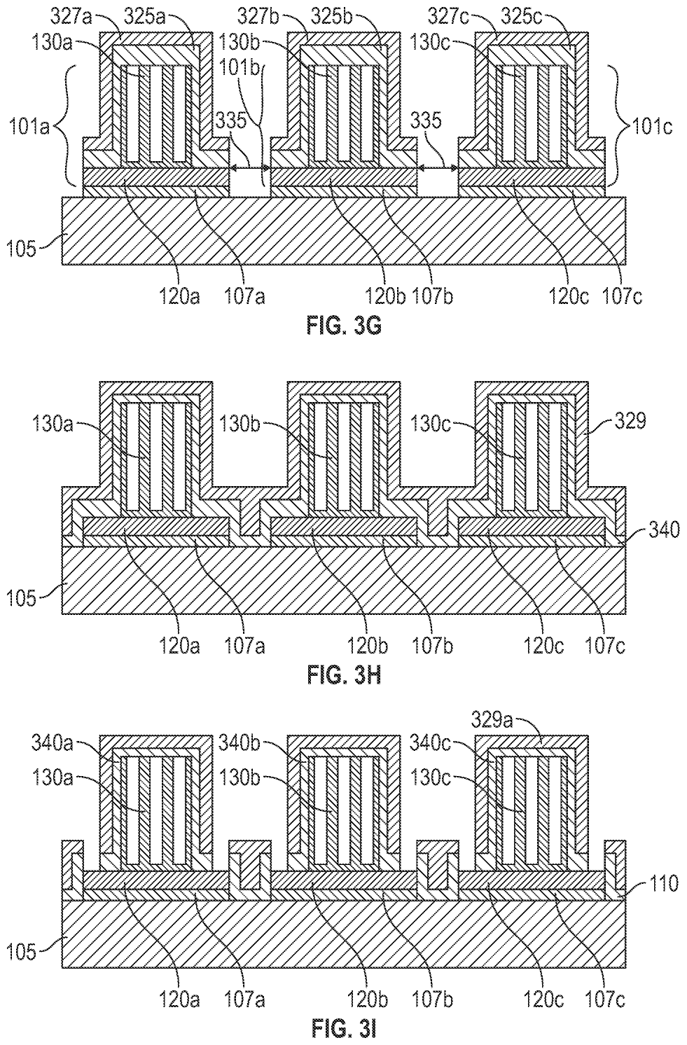

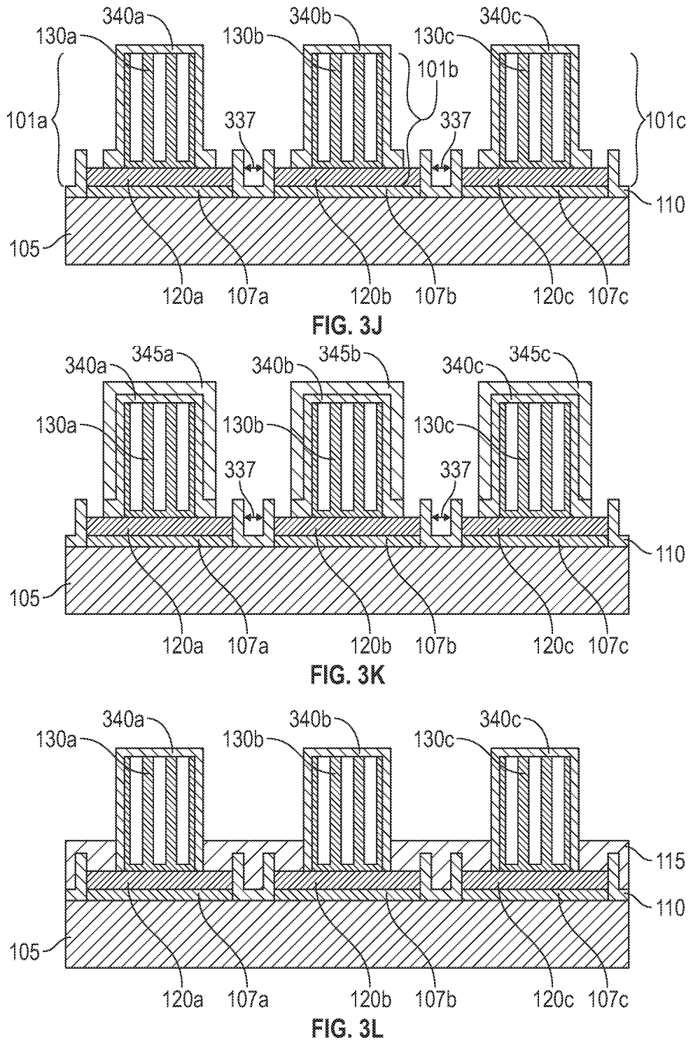

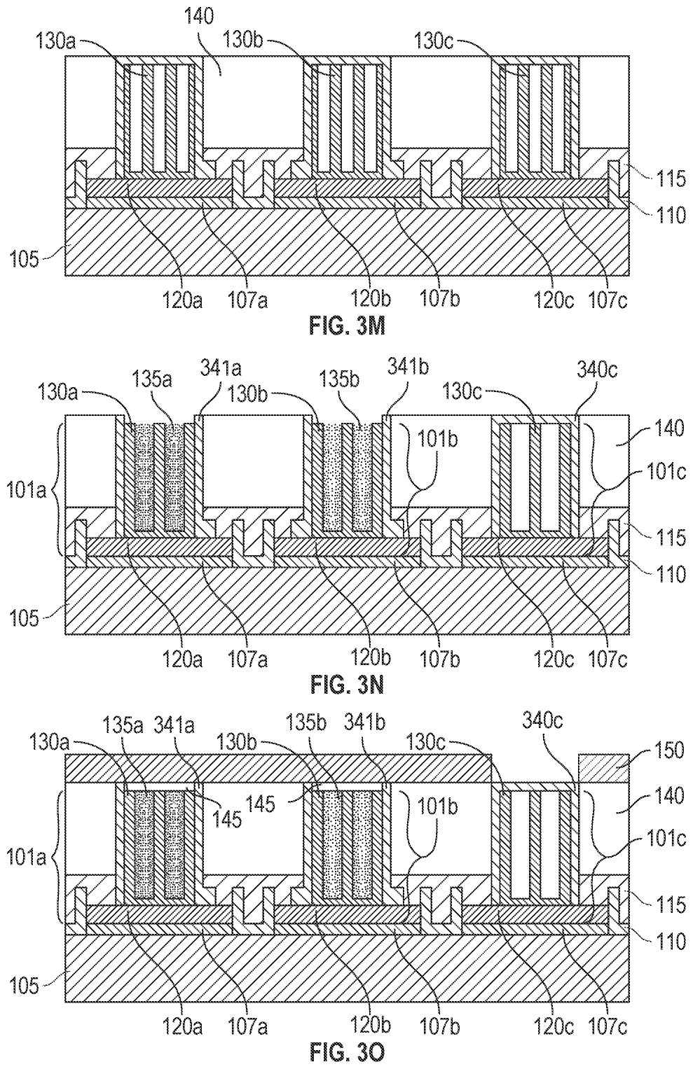

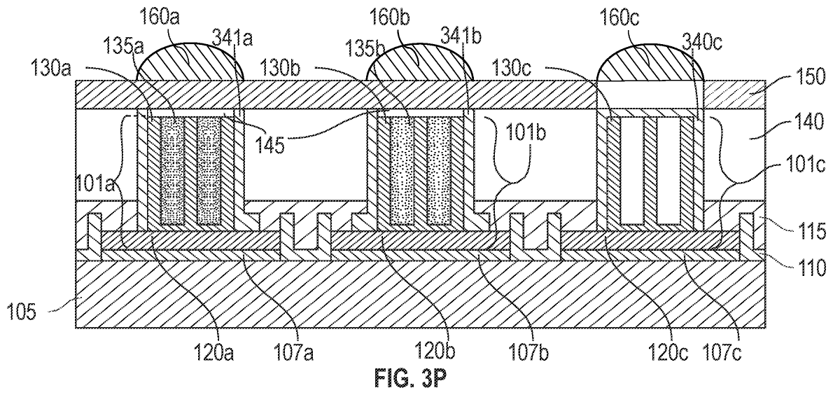

Referring to FIGS. 3A, 3B, 3C, 3D, 3E, 3F, 3G, 3H, 3I, 3J, 3K, 3L, 3M, 3N, and 3O, cross-sectional views of structures related to a process for fabricating semiconductor device 100 of FIG. 1 in accordance with some embodiments of the present disclosure are illustrated.

As shown in FIG. 3A, semiconductor device 200 may be attached to substrate 105. Semiconductor device 200 may include growth template 210, buffer layer 220, first semiconductor layer 231 containing n-GaN, second semiconductor layer 233 containing n-GaN, active layer 240, third semiconductor layer 250 (e.g., a p-GaN layer), etc. Semiconductor device 200 may be attached to substrate 105 via a bonding layer 305 (e.g., utilizing a metal bonding or any other suitable bonding process). In some embodiments, third semiconductor layer 250 (e.g., a p-GaN layer) may be bonded to substrate 105 via bonding layer 305.

As shown in FIG. 3B, one or more portions of semiconductor device 200 may be removed to expose a surface of first semiconductor layer 231. For example, growth template 210 and buffer layer 220 may be removed (e.g., utilizing ICP (inductively coupled plasma) etching techniques).

As shown in FIG. 3C, first semiconductor layer 231 may be processed to form a porous semiconductor layer 310. For example, first semiconductor layer 231 may be etched using chemical etching or any other suitable etching techniques to form nanopores having a nanoscale size (e.g., a size of the order of 1 nm to 1000 nm or larger). The porosity of porous semiconductor layer 310 (e.g., a fraction of the volume of the nanopores over a total volume of porous semiconductor layer 310) can be in the range of 10% to 90%. In some embodiments, a dimension (e.g., a diameter, a depth) of a nanopore in porous semiconductor layer 310 may be equal to or greater than 10 nm. In some embodiments, a diameter of a nanopore in porous semiconductor layer 310 may be between about 5 nm and about 100 nm. In some embodiments, a diameter of a nanopore in porous semiconductor layer 310 may be between about 1 nm and about 500 nm. In some embodiments, a diameter of a nanopore in porous semiconductor layer 310 is not greater than 500 nm. In some embodiments, a diameter of a nanopore in porous semiconductor layer 310 may be between about 10 nm and about 20 nm. In some embodiments, a depth of the nanopores may be about or greater than 1 μm. The nanopores may be dispersed in a three-dimensional space.

As shown in FIG. 3D, masks 321a, 321b, . . . , 321c and photoresists 323a, 323b, . . . , 323c may be formed on porous semiconductor layer 310. For example, a dielectric layer (e.g., a layer of silicon dioxide) and a layer of photoresist materials (e.g., gasses, polymers, ceramics, etc.) may be fabricated and patterned to form masks 321a, 321b, . . . , 321c and photoresists 323a, 323b, . . . , 323c utilizing suitable photolithography techniques, ICP etching techniques, etc.

As shown in FIG. 3E, nanoporous structures 130a, 130b, . . . , 130c may be formed by selectively removing one or more portions of porous semiconductor layer 310. For example, photoresists 323a, 323b, . . . , 323c may be removed. Porous semiconductor layer 310 may be etched to remove the portions of porous semiconductor layer 310 that are not covered by masks 321a, . . . , 321b, . . . , 321c. The etching of porous semiconductor layer 310 may create a plurality of trenches 331 that separate neighboring nanoporous structures 130a, 130b, . . . , 130c. The etching of porous semiconductor layer 310 may stop at the top layer of light-emitting structure 205 (e.g., second semiconductor layer 233).

As shown in FIG. 3F, photoresists 327a, 327b, . . . , 327c and masks 325a, 325b, . . . , 325c may be formed on nanoporous structures 130a, 130b, . . . , 130c. In some embodiments, photoresists 327a, 327b, . . . , 327c and masks 325a, 325b, . . . , 325c may be fabricated by depositing a dielectric layer (not shown) and a photoresist layer (not shown) on nanoporous structures 130a, 130b, . . . , 130c, along the sidewalls of nanoporous structures 130a, 130b, . . . , 130c, and on the top surface of light-emitting structure 205. The photoresist layer and the dielectric layer may then be patterned the dielectric layer to expose a plurality of portions of the top surface of light-emitting structure 205 (e.g., trenches 333 positioned between neighboring nanoporous structures 130a, 130b, . . . , 130c).

As shown in FIG. 3G, portions of light-emitting structure 205 and bonding layer 305 may be selectively removed to expose one or more portions of the top surface of substrate 105. For example, the portions of light-emitting structure 205 and bonding layer 305 that are not covered by masks 325a, 325b, . . . , 325c may be removed by etching light-emitting structure 205 and bonding layer 305. The selective removal of light-emitting structure 205 and bonding layer 305 may create LEDs 120a, 120b, . . . , 120c and bonding layer 107 (e.g., segments 107a, 107b, . . . , 107c) that are separated by trenches 335.

As shown in FIG. 3H, a dielectric layer 340 may be formed on nanoporous structures 130a, 130b, . . . , 130c and in trenches 335. Dielectric layer 340 may be and/or include a layer of silicon oxide, silicon nitride, and/or any other suitable dielectric material. As illustrated, dielectric layer 340 may cover the top surfaces and sidewalls of nanoporous structures 130a, 130b, . . . , 130c and the sidewalls of trenches 335. As such, dielectric layer 340 fill a portion of trenches 335. A photoresist layer 329 may be fabricated on dielectric layer 340 and may fill trenches 335.

As shown in FIG. 3I, dielectric layer 340 and photoresist layer 329 may be patterned to expose at least a portion of the top surface of each LED 120a-c. Dielectric layer 340 and photoresist layer 329 may be patterned using suitable photolithograph techniques and/or etching techniques in some embodiments. The portions of the patterned dielectric layer 340 that are formed between LEDs 120a-c are also referred to as dielectric layer 110. The portions of the patterned dielectric layer 340 that are formed on the top surface and along the sidewalls of nanoporous structures 130a-c are also referred to as dielectric layers 340a, 340b, . . . , 340c.

As shown in FIG. 3J, the patterned photoresist layer 329a may be removed to expose dielectric layers 110 and 340a-c. In some embodiments, dielectric layer 110 may fill a portion of each of trenches 335. The unfilled portions of trenches 335 are referred to herein as trenches 337.

As shown in FIG. 3K, negative photoresists 345a, 345b, and 345c may be fabricated on dielectric layers 340a, 340b, and 340c, respectively. As shown in FIG. 3L, a conductive layer 115 may be fabricated on dielectric layer 110 and the portions of the top surface of LEDs 120a, 120b, . . . , 120c that are not covered by nanoporous structures 130a, 130b, . . . , 130c. In some embodiments, conductive layer 115 may be fabricated by depositing a conductive material (e.g., metal Ti, Au, etc.) on negative photoresists 345a, 345b, and 345c and in trenches 337 and removing the conductive material deposited on negative photoresists 345a, 345b, and 345c and negative photoresists 345a, 345b, and 345c utilizing a lift-off process.

As shown in FIG. 3M, insulating materials 140 may be coated on conductive layer 115 and in the trenches between nanoporous structures 130a-c. In some embodiments, insulating materials 140 may include black glue.

As shown in FIG. 3N, one or more portions of dielectric layers 340a and 340b may be removed. For example, dielectric layer 341a and 341b may be formed by removing a top portion of dielectric layer 340a and a top portion of dielectric layer 340b, respectively. First quantum dots (QDs) 135a and second quantum dots (QDs) 135b may then be placed in nanoporous structures 130a and 130b, respectively. For example, first QDs 135a may be loaded into nanoporous structure 130a by infiltrating a liquid (such as toluene, polydimethylsiloxane (PDMS), etc.) containing first QDs into nanoporous structures 130a. Second QDs 135b may be loaded into second nanoporous structure 130b by infiltrating a liquid containing second QDs into second nanoporous structure 130b. In some embodiments, first QDs 135a and/or second QDs 135b may be placed in nanoporous structures 130a and 130b using an inkjet printing method.

As shown in FIG. 3O, a protection layer 145 may be fabricated on nanoporous structures 130a-130b. The protection layer 145 may include one or more materials that may protect the QDs from oxygen, moisture, and/or other environmental factors. For example, the protection layer 145 may include one or more layers of SiO₂, SiN, Al₂O₃, polydimethylsiloxane (PDMS), poly(methylmethacrylate) (PMMA), etc.

A color filter 150 may be deposited on the protection layer 145, nanoporous structures 130a-130b, and insulating materials 140. In some embodiments, color filter 150 may include one or more DBRs. Color filter 150 does not cover third nanoporous structure 130c in some embodiments. As shown in FIG. 3P, a plurality of micro-lenses 160a, 160b, . . . , 160c may be disposed on color filter 150.

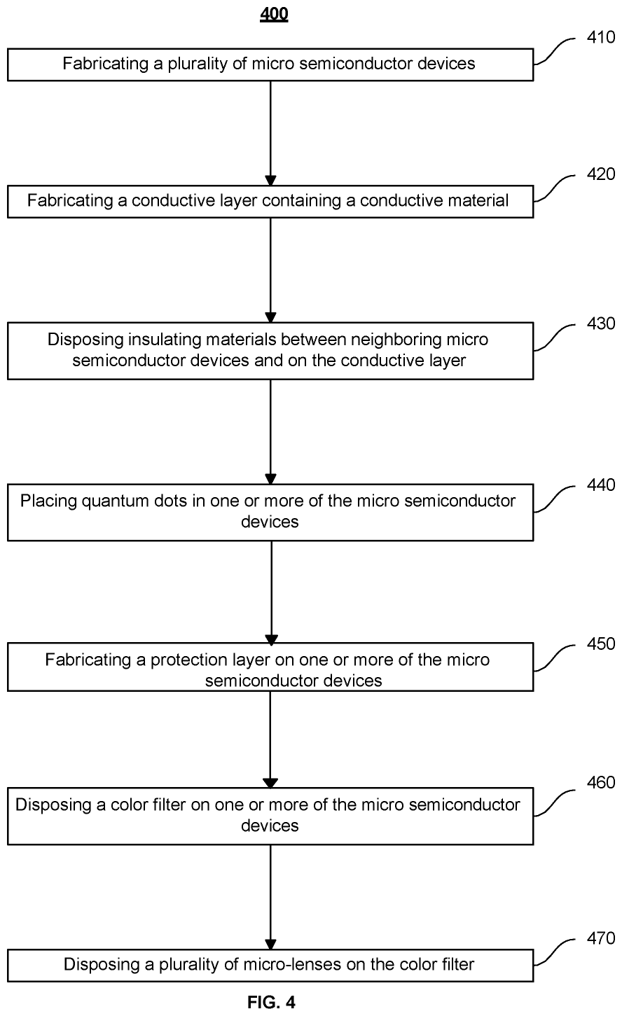

FIG. 4 is a flow chart illustrating an example process 400 for fabricating a semiconductor device with embedded quantum dots in accordance with some embodiments of the present disclosure.

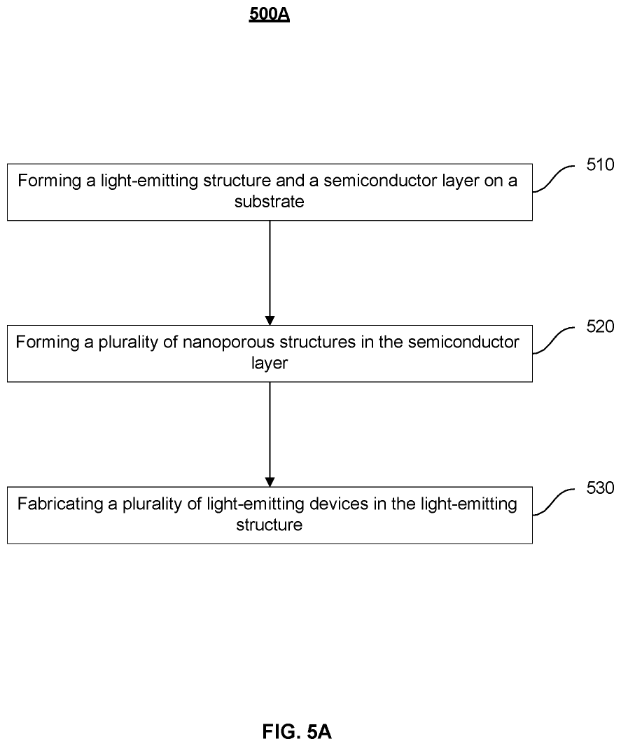

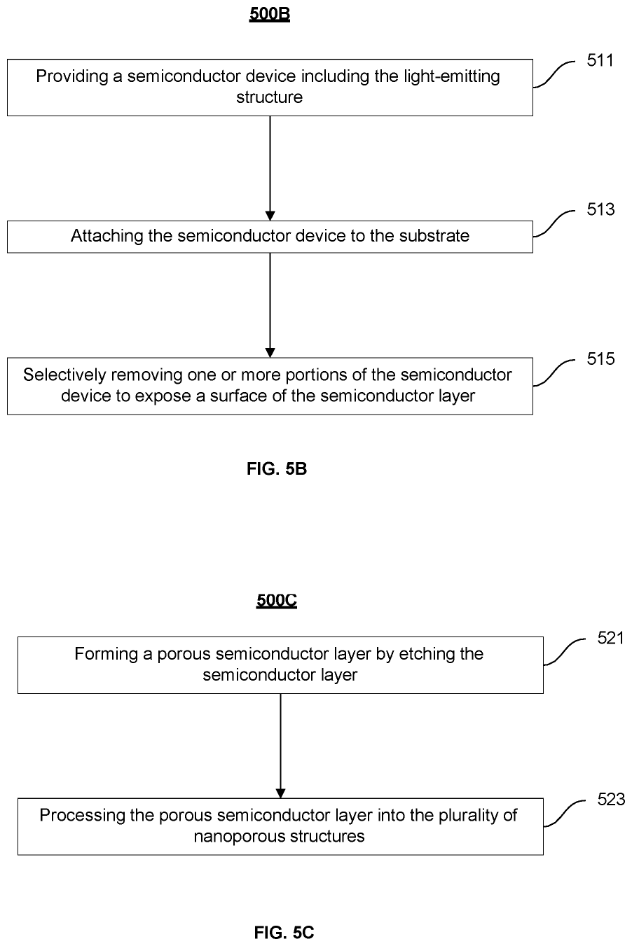

At block 410, a plurality of micro semiconductor devices may be fabricated. Each of the micro semiconductor devices may include a nanoporous structure fabricated on an LED (e.g., a micro-LED). The nanoporous structure may be embedded with suitable QDs for converting the light emitted by the LED into the light of certain wavelengths and/or color. In some embodiments, a first micro semiconductor device of the micro semiconductor devices may include a first nanoporous structure fabricated on a first top surface of a first light-emitting device (e.g., a central portion of the first top surface). A second micro semiconductor device of the micro semiconductor devices may include a second nanoporous structure fabricated on a second top surface of a second light-emitting device (e.g., a central portion of the second top surface). A third micro semiconductor device of the micro semiconductor devices may include a third nanoporous structure fabricated on a third top surface of a third light-emitting device (e.g., a central portion of the third top surface). The micro semiconductor devices may be micro semiconductor device 101a, 101b, . . . , 101c as described in connection with FIGS. 1 and 3M. In some embodiments, fabricating the micro semiconductor devices may involve performing one or more operations as described in connection with FIGS. 3A-3G and 5.

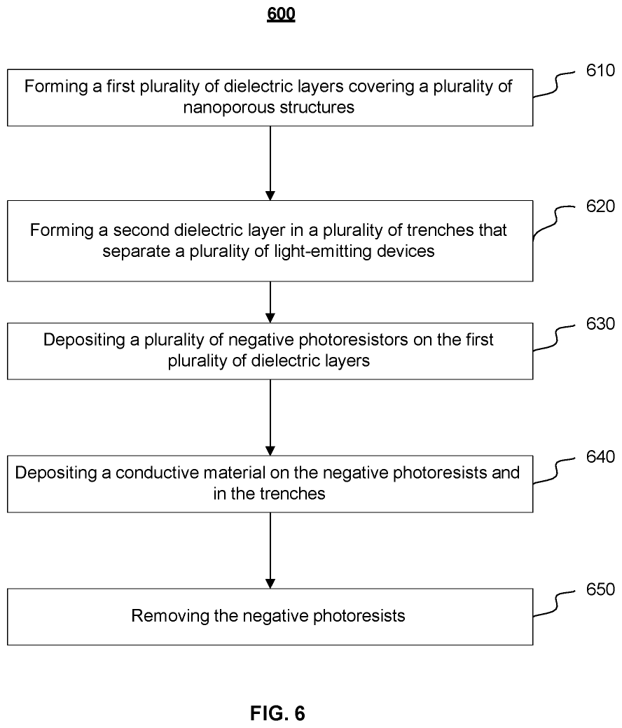

At block 420, a conductive layer may be fabricated. The conductive layer may include a conductive material, such as a metallic material (e.g., metal Ti, metal Au, etc.). The conductive layer may directly contact the first top surface of the first light-emitting device, the second top surface of the second light-emitting device, and the third top surface of the third light-emitting device to connect the light-emitting devices with one or more other circuit elements electrically. In some embodiments, one or more portions of the conductive layer are fabricated in a plurality of trenches that separate the neighboring light-emitting devices of the micro semiconductor devices. The conductive layer may be conductive layer 115 of FIG. 1 and may be fabricated by performing operations described in connection with FIGS. 3H-3L and 6.

At block 430, insulating materials may be disposed between the micro semiconductor devices and on the conductive layer. The insulating materials may be insulating materials 140 as described in connection with FIGS. 1 and 3M.

At block 440, quantum dots may be placed in one or more of the nanoporous structures of the micro semiconductor devices. For example, as described in connection with FIG. 3N, a first plurality of QDs 135a may be placed in the first nanoporous structure of the first micro semiconductor device for converting light produced by the first LED into light of a first color (e.g., red light). A second plurality of QDs 135b may be placed in the second nanoporous structure of the second micro semiconductor device for converting light produced by the second LED into light of a second color (e.g., green light).

At block 450, a protection layer may be fabricated on one or more of the micro semiconductor devices. As an example, the protection layer (e.g., the protection layer 145 as described in connection with FIG. 3O) may be formed on the first micro semiconductor device and the second micro semiconductor device by depositing one or more layers of materials that may prevent the QDs from oxidation, moisture, and/or other environmental factor, such as SiO₂, SiN, Al₂O₃, etc.

At block 460, a color filter may be disposed on one or more of the micro semiconductor devices and/or the protection layer. The color filter may be disposed on the first micro semiconductor device and the second micro semiconductor device and the insulating materials utilizing deposition, photolithography, etching, etc. techniques. In some embodiments, the color filter is not disposed on the third micro semiconductor device. The color filter may be color filter 150 as described in connection with FIGS. 1 and 3N.

At block 470, a plurality of micro-lenses may be formed on the color filter. For example, as described in connection with FIG. 1, a first micro-lens 160a, a second micro-lens 160b, and a third micro-lens 160b may be formed on the color filter. The first micro-lens 160a, the second micro-lens 160b, and the third micro-lens 160b may be formed on the first nanoporous structure, the second nanoporous structure, and the third nanoporous structure, respectively. The micro-lens may be formed by photolithography and etching processes in some embodiments.

FIGS. 5A, 5B, and 5C are flow charts illustrating example processes 500A, 500B, and 500C for fabricating micro semiconductor devices containing nanoporous structures in accordance with some embodiments of the present disclosure.

As shown, process 500A may start at block 510, where a light-emitting structure and a semiconductor layer may be formed on a substrate. The semiconductor layer may include any suitable semiconductor materials for forming nanoporous structures as described herein. In some embodiments, the semiconductor layer includes an n-doped II-V material (e.g., n-doped GaN). The light-emitting structure may produce light of a certain color. The light-emitting structure may include a first semiconductor layer, a second semiconductor layer, and an active layer fabricated between the first semiconductor layer and the second semiconductor layer. The first semiconductor layer may include a p-GaN layer. The first semiconductor layer may include an n-GaN layer and a u-GaN buffer layer. The light-emitting structure and the semiconductor layer may be light-emitting structure 205 and semiconductor layer 231 as described in connection with FIGS. 2, 3A, and 3B, respectively.

In some embodiments, the light-emitting structure and the semiconductor layer may be formed on the substrate by performing one or more operations as described in FIG. 5B. At block 511, a semiconductor device including the light-emitting structure may be provided. In some embodiments, the light-emitting structure may further include a substrate on which the first semiconductor layer is formed. The semiconductor device may be and/or include, for example, semiconductor device 200 as described in connection with FIG. 2.

At block 513, the semiconductor device may be attached to the substrate. For example, the semiconductor device may be bonded to the substrate utilizing a metal bonding process as described in connection with FIG. 3A. In some embodiments, a p-GaN layer of the semiconductor device may be bonded to the substrate via a bonding layer.

At block 515, one or more portions of the semiconductor device may be selectively removed to expose a surface of the semiconductor layer. For example, the growth template of the semiconductor device and/or the buffer layer may be removed as described in connection with FIG. 3B. The buffer layer may be removed utilizing ICP etching techniques in some embodiments.

Referring back to FIG. 5A, at block 520, a plurality of nanoporous structures may be formed in the semiconductor layer. The nanoporous structures may be separated by a plurality of trenches (also referred to as the “first plurality of trenches”). In some embodiments, the nanoporous structures may be formed by performing one or more operations depicted in FIG. 5C. At block 521, a porous semiconductor layer may be formed by etching the semiconductor layer. For example, the semiconductor layer may be etched to form a plurality of nanopores as described in connection with FIG. 3C.

At block 523, the porous semiconductor layer may be processed into the plurality of nanoporous structures. For example, a plurality of portions of the porous semiconductor layer may be selectively removed, for example, utilizing suitable photolithograph techniques, ICP techniques, etc. More particularly, for example, a dielectric layer (e.g., a layer of SiO₂) may be deposited on the nanoporous structures. A photoresist layer may be fabricated on the SiO₂ layer. The photoresist layer and the dielectric layer may then be patterned (e.g., by selectively removing the photoresist layer by photolithograph and selectively removing one or more portions of the SiO₂ layer by ICP). The porous semiconductor layer may be etched and the portions of the porous semiconductor layer that are not covered by the masks may be removed. The selective removal of the portions of the porous semiconductor layer may create the nanoporous structures separated by the first plurality of trenches. In some embodiments, the etching of the porous semiconductor layer may stop at the light-emitting structure of the semiconductor device. The porous semiconductor layer may be processed into the plurality of nanoporous structures as described in connection with FIGS. 3D-3E.

Referring back to FIG. 5A, at block 530, a plurality of light-emitting devices may be fabricated in the light-emitting structure. For example, the light-emitting structure may be selectively etched to form the plurality of light-emitting devices. Each of the light-emitting devices may be a micro-LED in some embodiments. The bonding layer may also be etched (e.g., IBE etched) into multiple segments in some embodiments. Each of the light-emitting devices may be bonded to the substrate via a respective segment of the bonding layer. Fabricating the plurality of light-emitting devices may involve performing the operations as described in connection with FIGS. 3F-3G.

Referring to FIG. 6, a flow chart of an example process 600 for fabricating a conductive layer that provides electrical connections between light-emitting devices and one or more other devices is illustrated.

At block 610, a first plurality of dielectric layers covering a plurality of nanoporous structures may be fabricated. The first plurality of dielectric layers may be formed on the top surfaces and sidewalls of the nanoporous structures. The first plurality of dielectric layers may be dielectric layers 340a, 340b, and 340c as described in connection with FIGS. 3I-3J above.

At block 620, a second dielectric layer may be formed in a plurality of trenches that separate a plurality of light-emitting devices. Each of the nanoporous structures (e.g., nanoporous structures 130a-c of FIG. 3I-3J) is formed on a respective light-emitting device (e.g., LEDs 120a-c of FIG. 3I-3J). The second dielectric layer may be dielectric layer 110 as described in connection with FIGS. 3I-3J. The first plurality of dielectric layers and the second dielectric layer may be formed by performing operations described in connection with FIGS. 3H-3J above.

At block 630, a plurality of negative photoresists may be deposited on the first plurality of dielectric layers. The negative photoresists may be negative photoresists 345a, 345b, . . . , 345c as described in connection with FIG. 3K above. The negative photoresists do not contact the second dielectric layer in some embodiments.

At block 640, a conductive material may be deposited on the negative photoresists and in the trenches. The conductive material may be, for example, a metallic material such as metal Ti, metal Au, etc.

At block 650, the negative photoresists may be removed. The removal of the negative photoresists may also remove the conductive material deposited on the negative photoresists and may thus form the conductive layer as shown in FIG. 3L.

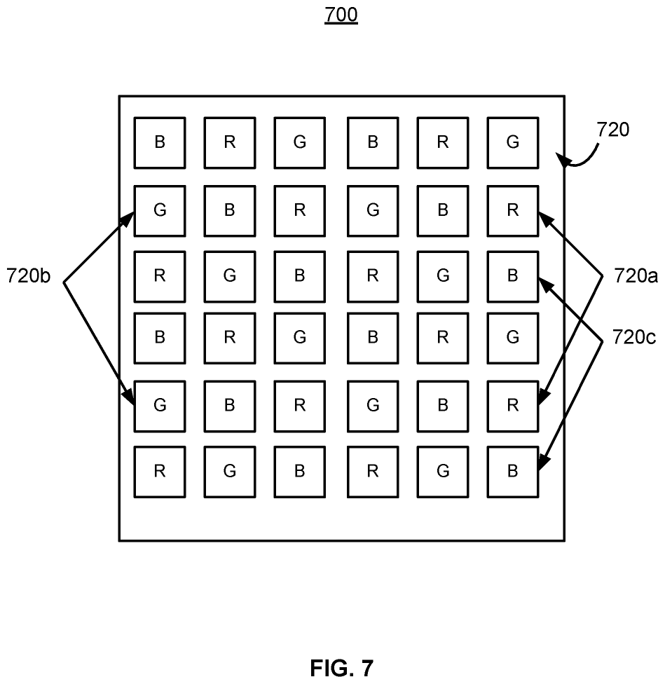

FIG. 7 depicts a schematic diagram illustrating an example pixel arrangement of an example display device 700 in accordance with some embodiments of the present disclosure. Display device 700 may be incorporated into any suitable computing device, such as mobile phones, laptops, desktops, tablet computer devices, wearable computing devices (e.g., watches, eyeglasses, head-mounted displays, virtual reality headsets, activity trackers, clothing, etc.), televisions, etc. Display device 700 may be of any suitable size.

As illustrated, display device 700 may include micro semiconductor devices 720 arranged in one or more arrays. Micro semiconductor devices 720 may emit light of varying colors (e.g., red, green, blue, etc.). For example, a first plurality of micro semiconductor devices 720a may emit light of a first color (also referred to as the “first plurality of micro semiconductor devices”). A second plurality of micro semiconductor devices 720b may emit light of a second color (also referred to as the “second plurality of micro semiconductor devices”). A third plurality of micro semiconductor devices 720c may emit light of a third color (also referred to as the “third plurality of micro semiconductor devices”). In some embodiments, the first color, the second color, and the third color may be a red color, a green color, and a blue color, respectively. Each of micro semiconductor devices 720 may include a micro semiconductor device as described herein. For example, a micro semiconductor device 720a may include micro semiconductor device 101a embedded with first QDs 135a of FIG. 1. A micro semiconductor device 720a may include micro semiconductor device 101b embedded with second QDs 135b of FIG. 1. A micro semiconductor device 720c may include micro semiconductor device 101c of FIG. 1. Micro semiconductor devices 720a, 720b, and 720c may further include micro-lenses 160a, 160b, and 160c, respectively. Color filter 150 may be fabricated between micro-lenses 160a-b and micro semiconductor devices 101a-b.

A micro semiconductor device 720a, a micro semiconductor device 720b, and a micro semiconductor device 720c may form a pixel. As such, micro semiconductor devices 720 correspond to a plurality of pixels of display device 700. Each of the pixels may include a micro semiconductor device 720a, a micro semiconductor device 720b, and a micro semiconductor device 720c. In some embodiments, a micro semiconductor device 720 may also be referred to as a sub-pixel of display device 700 or a pixel of display device 700.

While micro semiconductor devices 720 are arranged in FIG. 7 in certain manners, this is merely illustrative. Micro semiconductor devices 720 may be arranged in any suitable manner to form pixels of a display device. For example, two micro semiconductor devices 720b may be positioned between a micro semiconductor device 720a and a micro semiconductor device 720c in some embodiments. As another example, micro semiconductor devices located in different rows of micro semiconductor devices 720 (e.g., a micro semiconductor device 720a in a first row and semiconductor devices 720b and 720c in a second row of micro semiconductor devices 720) may form red, green, and blue pixels of the display device.

Display device 700 may include a substrate (not shown). The substrate may include any suitable component for supporting micro semiconductor devices and/or any other suitable component of display device 700. In one implementation, substrate may include a driver circuit (e.g., one or more CMOS drivers, a TFT, etc.). In another implementation, the substrate does not include a driver circuit. The substrate may include a plurality of conductive lines (e.g., rows and/or columns of conductive lines) connecting one or more of the micro semiconductor devices disposed on the substrate.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a first nanoporous structure fabricated on a first surface of a first light-emitting device, wherein a first plurality quantum dots are placed in the first nanoporous structure for converting light emitted by the first light-emitting device into light of a first color;
a second nanoporous structure fabricated on a second surface of a second light-emitting device, wherein a second plurality quantum dots are placed in the second nanoporous structure for converting light emitted by the second light-emitting device into light a second color;
a third light-emitting device that emits light of a third color; and
a conductive layer comprising a conductive material, wherein at least a portion of the conductive layer is fabricated in a first trench between the first light-emitting device and the second light-emitting device, and wherein the conductive layer contacts the first surface of the first light-emitting device, the second surface of the second light-emitting device, and a third surface of the third light-emitting device.

2. The apparatus of claim 1, wherein a first lateral dimension of the first light-emitting device is greater than a second lateral dimension of the first nanoporous structure.

3. The apparatus of claim 1, further comprising:
a substrate comprising a CMOS circuit; and
a dielectric layer, wherein at least a first portion of the dielectric layer is positioned between the substrate and the conductive layer.

4. The apparatus of claim 1, further comprising a color filter on the first nanoporous structure and the second nanoporous structure.

5. The apparatus of claim 4, further comprising a plurality of micro-lenses fabricated on the color filter.

6. The apparatus of claim 1, wherein the conductive material comprises a metallic material.

7. The apparatus of claim 1, further comprising a third nanoporous structure on the third light-emitting device, wherein no quantum dots are placed in the third nanoporous structure.

8. The apparatus of claim 1, wherein at least a portion of the conductive layer is fabricated in a second trench between the second light-emitting device and the third light-emitting device.

9. The apparatus of claim 1, wherein each of the first light-emitting device, the second light-emitting device, and the third light-emitting device is a micro light-emitting device.

10. The apparatus of claim 1, wherein the first surface of the first light-emitting device is a top surface of an n-GaN layer of the first light-emitting device.

11. The apparatus of claim 1, further comprising insulating materials disposed on the conductive layer and in a plurality of trenches between the first nanoporous structure, the second nanoporous structure.

12. A method for fabricating a display device, comprising:
fabricating a plurality of micro semiconductor devices, wherein a first micro semiconductor device of the micro semiconductor devices comprises a first nanoporous structure fabricated on a first top surface of a first light-emitting device, wherein a second micro semiconductor device of the micro semiconductor devices comprises a second nanoporous structure fabricated on a second top surface of a second light-emitting device, and wherein a third micro semiconductor device of the micro semiconductor devices comprises a third nanoporous structure fabricated on a third top surface of a third light-emitting device; and
fabricating a conductive layer comprising a conductive material, wherein the conductive layer contacts the first top surface of the first light-emitting device, the second top surface of the second light-emitting device, and the third top surface of the third light-emitting device, and wherein at least one portion of the conductive layer is fabricated in a trench between the first light-emitting device and the second light-emitting device.

13. The method of claim 12, further comprising:
placing a first plurality of quantum dots in the first nanoporous structure for converting light produced by the first light-emitting device into light of a first color;
placing a second plurality of quantum dots in the second nanoporous structure for light produced by the second light-emitting device into light of a second color; and
fabricating a protection layer on the first nanoporous structure and the second nanoporous structure.

14. The method of claim 12, further comprising:
disposing a DBR on one or more of the micro semiconductor devices; and
disposing a plurality of micro-lenses on the DBR.

15. The method of claim 12, wherein fabricating the plurality of micro semiconductor devices comprises:
forming a light-emitting structure and a semiconductor layer on a substrate;
forming a plurality of nanoporous structures in the semiconductor layer, and
fabricating a plurality of light-emitting devices in the light-emitting structure.

16. The method of claim 15, wherein fabricating the light-emitting structure and the semiconductor layer on the substrate comprises:
attaching a semiconductor device to the substrate; and
selectively removing one or more portions of the semiconductor device to expose a surface of the semiconductor layer.

17. The method of claim 16, wherein forming the plurality of nanoporous structures in the semiconductor layer comprises:
forming a porous semiconductor layer by etching the semiconductor layer; and
processing the porous semiconductor layer into the plurality of nanoporous structures by etching the porous semiconductor layer.

18. The method of claim 12, wherein fabricating the conductive layer comprises:
depositing a metallic material on a first portion of the first surface of the first light-emitting device that is not covered by the first nanoporous structure, a second portion of the second surface of the second light-emitting device that is not covered by the second nanoporous structure, and a third portion of the third surface of the third light-emitting device that is not covered by the third nanoporous structure.

19. The method of claim 18, wherein fabricating the conductive layer comprises:
forming a first plurality of dielectric layers covering the plurality of micro semiconductor devices;
forming a second dielectric layer in the trenches;
depositing a plurality of negative photoresists on the first plurality of dielectric layers; and
depositing a conductive material on the negative photoresists and in the trenches.

20. The method of claim 19, wherein fabricating the conductive layer further comprises removing the negative photoresists.
